(19) United States
(12) Patent Application Publication
(10) Pub. No.: US 2001/0008710 A1
(43) Pub. Date: Jul. 19, 2001

(54) TRANSPARENT CONDUCTIVE FILM HAVING HIGH TRANSMISSION IN THE INFRARED REGION

(76) Inventors: HIROSHI TAKATSUJI, TOKYO-TO (JP); TADASHI HIROMORI, OTSU-SHI (JP); SATOSHI TSUJI, HADANO-SHI (JP)

Correspondence Address: ROBERT M TREPP, IBM CORPORATION, P O BOX 218, YORKTOWN HEIGHTS, NY, 10598

(21) Appl. No.: 09/384,069

(22) Filed: Aug. 26, 1999

(30) Foreign Application Priority Data
Aug. 26, 1998 (JP) 10-239858

(51) Int. Cl. B32B 19/00; C23C 14/34; B32B 17/06; B32B 9/00

(52) U.S. Cl. 428/689; 204/192.29; 204/192.26; 204/192.27; 204/192.28; 428/688; 428/426

(57) ABSTRACT

By heating a film comprising an indium-zinc oxide (IZO) as its main component under an ambient atmosphere of low-concentration oxygen, a transparent conductive film showing a high transmittance of about 80% or more in a wavelength region of 450 to 3200 nm can be obtained. The electrical resistivity of the transparent conductive film is about 3.0×10⁻³ Ω-cm or less. A film with IZO as its main component is substantially in amorphous form or microcrystalline form, and such a film may be fabricated by sputtering.

### FIELD OF THE INVENTION

The present invention relates to a transparent conductive film that comprises an indium-zinc oxide (IZO) as its main component, and more particularly to a transparent conductive film having high transmission in the infrared region.

### BACKGROUND OF THE INVENTION

A transparent conductive film with higher conductance and higher transmittance has been obtained with advancement in the fabrication technique, and in recent years, the range of application has been enlarged. The transparent conductive film has been used as transparent electrodes for liquid crystal, electro-luminescent, electro-chromic, and plasma displays and has made a great contribution to the spread of panel displays. The transparent conductive film is also used as an antistatic film for a cathode-ray tube (CRT) display screen or an instrument window. Furthermore, it is well known to use the transparent conductive film in a cloud-proof and frost-proof heating element or a heat ray reflection film for the window glass of aircrafts, automobiles, and buildings.

Generally, in these applications, the transparent conductive film requires high visible-light transmittance in addition to high conductance, superior durability, and process ability such as film formation. Particularly, in the case where the transparent conductive film is used as a heat ray reflection film, a high reflectance with respect to light with a wavelength in the infrared region has been required and achieved.

However, as the application range of the transparent conductive film has spread to the transparent electrodes of solar cells and the window material for communication systems or measuring instruments, light-transmitting property has been required in a wider wavelength region.

Presently, the most widely used transparent conductive film comprises an indium-tin oxide (ITO) film and a tin oxide (SnO₂) film. However, according to a graph showing the spectral characteristics of the ITO and SnO₂ films described in “G. Frank et al., Thin Solid Films, vol. 77, p. 107 (1981),” it is found that although these metal oxide films have a transmittance of 80% or more in a visible-light region, the light transmittance is rapidly reduced at a wavelength exceeding about 1000 nm and extremely low in an infrared region.

Published Unexamined Japanese Patent Application No. 8-227614 (1996, corresponding U.S. patent application, Ser. No. 335615) shows that the light absorption coefficient of a conductively doped indium-zinc oxide (IZO) film is considerably low compared with that of the ITO film. However, this conductively doped IZO film also increases its absorption coefficient at the long wavelength side beyond about 700 nm and rapidly increases the absorption coefficient at the long wavelength side beyond about 1200 nm.

An object of the present invention is to provide a transparent conductive film having high transmission in a wide wavelength region from a visible ray to an infrared ray. Particularly, the object is to provide a transparent conductive film that exhibits higher transmittance rather than a conventional transparent conductive film in the infrared wavelength region.

Another object of the present invention is to provide a method of fabricating a transparent conductive film having high transmission in a wide wavelength region from a visible ray to an infrared ray.

### SUMMARY OF THE INVENTION

According to the present invention, a film comprising indium-zinc oxide (IZO) as its main component is heated under a low-oxygen atmosphere. This heating process can fabricate a transparent conductive film that shows a high transmittance of about 70% or more in a wavelength region from a visible ray (450 to 800 nm) to an infrared ray (800 to 3200 nm). At up to a film thickness of about 200 nm, such a high transmittance can be achieved. The electrical resistivity of this transparent conductive film is about 3.0×10⁻³ Ω-cm or less.

According to a preferred aspect of the present invention, a film of about 100 nm in thickness with an indium-zinc oxide (IZO) as its main component is heated at about 230 to about 300° C. under an ambient atmosphere of low-concentration oxygen. This heating process can fabricate a transparent conductive film that shows a high transmittance of about 80% or more in a wide wavelength region from a visible ray to an infrared ray.

The film of the present invention comprising IZO as its main component and preferably comprises zinc from about 5 to about 20 atomic % and indium from about 5 to about 40 atomic %. Furthermore, dopants may be added to obtain low electrical resistivity.

The film of the present invention comprises IZO as its main component and is substantially in an amorphous form or is a film comprising microcrystals less than 250 Å. The film may be in an amorphous form containing microcrystals. Such films can be formed by sputtering.

The film of the present invention comprises a transparent conductive film superior in light transmittance in a wide wavelength region from visible light to infrared ray such as from 450 to 3200 nm.

### BRIEF DESCRIPTION OF THE DRAWING

These and other features, objects, and advantages of the present invention will become apparent upon consideration of the following detailed description of the invention when read in conjunction with the drawing in which:

FIG. 1 is a graph in which the light transmittance of an IZO film fabricated according to the present invention is compared with those of a conventional unheated ITO film , an ITO film heated in the same way as the present invention, and an unheated IZO film; and

FIG. 2 is a graph showing the light transmittances of IZO films obtained according to the examples of the present invention.

### DESCRIPTION OF THE PREFERRED EMBODIMENT

The present invention is based on the found fact that if a film comprising indium-zinc oxide (IZO) as its main component (hereinafter referred to as an IZO film) is heated in an ambient atmosphere of low-concentration oxygen, the transmittance of the IZO film in the infrared region will become higher compared with an unheated film. As is well known to those skilled in the art, the thermal deoxidization process reduces the transmittance of the ITO film, particularly in the infrared region.

The IZO film can be formed with the spray-pyrolysis method as described in Japanese Patent Application No. 7-10601, the coating method as described in Japanese Patent Application No. 6-234521, by chemical vapor deposition (CVD), or by deposition. But, in this embodiment, a description will be made of the IZO film formed by the sputtering method, as described in Japanese Patent Application No. 6-318406.

For the IZO film by the sputtering method, a sintered compact of composite oxides containing both indium oxide (In₂O₃) and zinc oxide (ZnO) was employed as target material, and the IZO film was formed with an ordinary sputtering system. The target material contains indium (In) in the range from about 5 to about 40 atomic % and zinc (Zn) in the range from about 5 to about 20 atomic %. The target material is available, for example, from Idemitsu Kosan located in Japan. The target material may contain tin (Sn), aluminum (Al), gallium (Ga), germanium (Ge), silicon (Si), zirconium (Zr), or titanium (Ti), as the third metal element. If the IZO film contains these third metal elements as dopants, the electrical resistivity can be adjusted.

A substrate is positioned in a sputtering system equipped with the aforementioned target material. The substrate may be glass, single crystal, semiconductor, plastic or the like. However, in order to take advantage of the high visible-light/infrared-ray transmitting property of the IZO film of the present invention, a transparent substrate to both visible light and infrared rays is suitable. The substrate may further have a film deposited on the entire surface or a patterned film. The film may comprise a metal, an inorganic compound such as an oxide and a nitride, or a polymer. Moreover, the substrate may include structures such as write heads, electronic devices, electric elements, optical elements, and sensors. The substrate temperature is between room temperature and about 400° C., preferably between room temperature and about 250° C. If the substrate temperature is too high, there will arise problems that the substrate will be deformed and that the crystal size comprised in the IZO film will tend to be larger. The sputtering system produces a vacuum of at least about 8.0 x 10⁻⁴ Pa and preferably a vacuum in the range from about 0.5 to about 4.0×10⁻⁴ Pa. Then, inert gas, such as argon (Ar) gas, and oxygen gas are introduced as an atmosphere gas to the chamber of the system in the range from about 2 to about 8 mTorr. It is desirable that the oxygen concentration in the atmosphere gas be in the range from about 0.6 to about 10%. In order to excite the atmosphere gas into plasma, appropriate voltage is applied between electrodes in the system. The applied voltage varies depending upon each factors, such as the features of the sputtering system to be used, the vacuum degree of the sputtering system, and the kinds of substrates. The applied voltage is usually about 200 to about 500 V. After a predetermined thickness has been obtained, the substrate is taken out of the sputtering system.

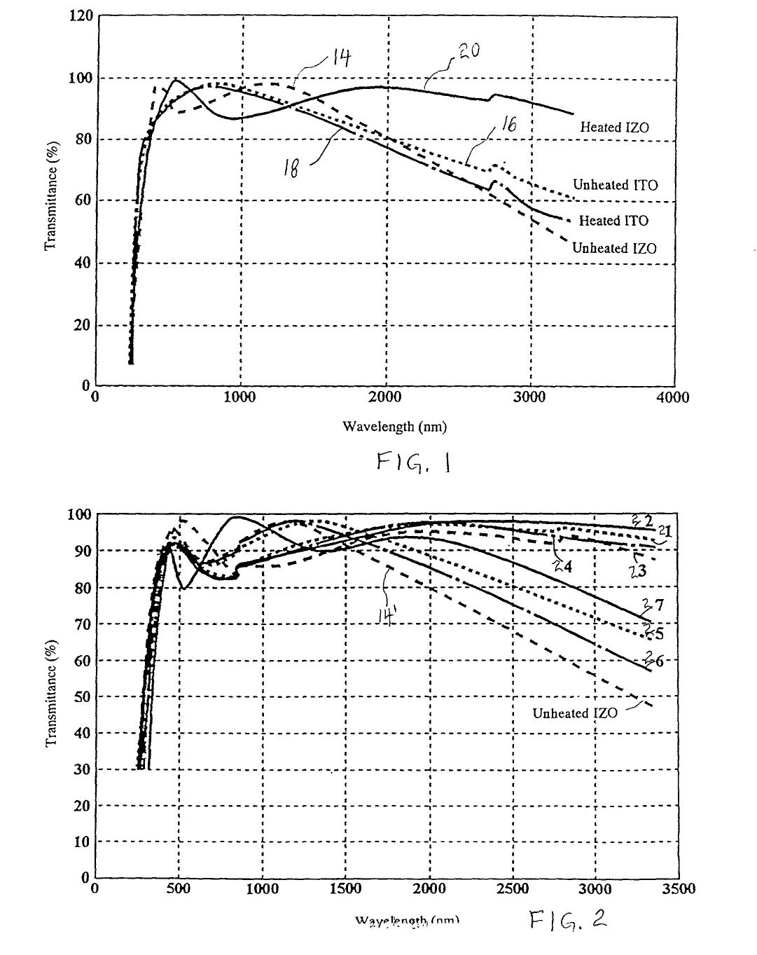

The obtained IZO film contains zinc in the range from about 5 to about 20 atomic % and indium in the range from about S to about 40 atomic %. The IZO film may contain the aforementioned third metal element as a dopant. It is desirable that the obtained IZO film be in the amorphous or microcrystalline form. It has been found that the conductance of the crystallized IZO film is low. It is preferable that the electrical resistivity of the IZO film obtained in this embodiment be about 1.0 mΩ-cm or less. The visible-light/infrared-ray transmittance spectrum of the deposited IZO film before heating is shown by curve 14 in FIG. 1. It is found that although weak absorption occurs near a visible-light region of 700 nm, the light-transmitting characteristic of this IZO film is almost similar to that of the unheated ITO film shown by curve 16 or the heated ITO film shown by curve 18. That is, in the IZO film before heating, the transmittance shown by curve 14 is reduced in the infrared wavelength region, and only a transmittance lower than about 80% is obtained, particularly in the region of a long wavelength exceeding 2000 nm.

Next, the obtained IZO film is heated under an ambient atmosphere of low-concentration oxygen. The ambient atmosphere of low-concentration oxygen means an ambient atmosphere that does not contain oxygen with a concentration higher than 21% which is the oxygen concentration in air. For instance, it is an ambient atmosphere comprising the atmosphere gas, nitrogen, or inert gas such as argon. It is preferable that this heating process be performed under an ambient atmosphere of nitrogen; however, it can be easily performed under the normal air. The heating process is performed in the range from about 10 to about 120 minutes at a temperature in the range between about 150 to about 350° C., preferably at a temperature in the range between about 230 to about 300° C. If the substrate temperature is higher than 300° C., there will be a possibility that the substrate will be deformed or crystallization of the IZO film will reduce the conductance. It has been confirmed by X-ray diffraction measurement that the IZO film after heating is amorphous or keeps a non-crystal structure.

The visible-light/infrared-ray transmittance spectrum of the deposited IZO film after heating is shown by curve 20 in FIG. 1. In FIG. 1, the ordinate represents transmittance and the abscissa represents the wavelength of radiant energy. The transmittance spectrum with its basic absorption end shifted to a slightly long wavelength side is obtained. This shows that the heating process causes some structural change to occur in the substance forming the IZO film. It is also shown that in the IZO film before heating, the film exhibits lower transmittance in the infrared wavelength region as the wavelength becomes longer as shown by curve 14, while in the IZO film after heating, the film exhibits the transmittance of about 90% wholly as shown by curve 20 in FIG. 1.

The electrical resistivity of the heated IZO film was about 3.0×10⁻³ Ω-cm or less. It is relatively high compared with the electrical resistivity of the IZO film before heating; however, it is considered practically negligible.

The IZO film can be patterned by using an acid solution, such as hydrochloric acid, nitric acid, or oxalic acid, as an etchant. For example, it is preferable that the IZO film be etched at a temperature in the range from about 20 to about 45° C. with the etchant of an oxalic acid solution in the range from about 1 to about 10 wt %.

Since the IZO transparent conductive film of the present invention has a transmittance as high as the conventional ITO transparent conductive film, even at a visible-light wavelength region, it can also be used as the conventional transparent conductive film. Particularly, by taking advantage of the characteristic exhibiting high transmittance even in the infrared wavelength region, the IZO film can be utilized, for example, in transparent electrodes for a solar cell.

In addition, in the chip-on glass (COG) technique, if the IZO transparent conductive film of the present invention is used as the I/O pad electrode on a glass substrate. Then when electronic devices are soldered on the glass substrate, the devices can be easily soldered by emitting an infrared beam to the back surface of the glass substrate.

Furthermore, in recent years, infrared rays are increasingly being utilized as communication media. If the IZO transparent conductive film of the present invention were used as a shielding material for the receiving and/or transmitting units, particularly a window-shielding material, then a leakage of noise and an invasion of external noise can be prevented without reducing the flux of an infrared ray. Of course, the IZO transparent conductive film of the present invention is not limited to the application of communication systems but is also useful as a shielding material for devices that utilize visible light or infrared rays, such as measuring instruments, sensors, infrared lamp heaters, and infrared lasers.

### EXAMPLE 1

A glass substrate was set in a DC magnetron sputtering system, and the pressure within the chamber thereof was reduced down to a pressure of about 0.5×10⁻⁴ Pa. For the target material, the sintered body of oxide compounds of indium and zinc (which includes indium by about 34.4 atomic % and zinc by about 7.0 atomic %) was employed. Then, argon gas containing oxygen gas by about 6% was introduced at a pressure of about 4.0 mTorr, and the substrate temperature was 215° C. RF voltage of −400 V was applied to the target material, and an IZO film with the thickness of about 100 nm was formed on the glass substrate by sputtering. The film thickness was measured with a step height measurement tool.

The substrate with the IZO film deposited thereon was taken out from the sputtering system and conveyed to a heating chamber. The heating chamber was filled with nitrogen gas and heated to 280° C. At a temperature of 280° C., the IZO film was heated for 120 min along with the substrate. After the substrate with the IZO film deposited thereon has been cooled down to room temperature, it was taken out.

For the transmittance of the obtained IZO film, the glass substrate was measured with a UV-VIS-IR spectrometer (Varian Cary 5G). It showed a transmittance of 80% or more at a wavelength of 450 to 3200 nm as shown by curve 20 in FIG. 1. The electrical resistivity of the obtained IZO film was also measured by four-point-probe method, and the resistivity was 1.2 mΩ-cm.

### COMPARATIVE EXAMPLE

An ITO film was formed and heated in the same procedure as described in Example 1. For the obtained ITO film, the transmittance and the electrical resistivity were measured. The obtained results are shown in Table 1 and by curve 14 in FIG. 1.

### EXAMPLES 2 THROUGH 7

An IZO film was formed in the same procedure as the Example 1, except for the substrate temperature during film formation and for the heating temperature listed in Table 1. The results are shown in Table 1 and by curves 14′, and 21-26 in FIG. 2. In FIG. 2 the ordinate represents transmittance and the abscissa represents the wavelength of radiant energy.

TABLE 1

| | Substrate | | | Electrical | | | | |
|---|---|---|---|---|---|---|---|---|
| | temperature | | | resistivity | | | | |
| | during film | Film | Heating | (mΩ cm) | | | | |
| | formation | thickness | temperature | Before | After | Transmittance (%) | | |
| Samples | (° C.) | (nm) | (° C.) | heating | heating | @ 800 nm | @ 2500 nm | @ 3000 nm |
| Unheated | 215 | 86 | | 0.31 | | 88 | 63 | 53 |
| Izo | | | | | | | | |
| Example 1 | 215 | 86 | 280 | 0.31 | 1.2 | 84 | 95 | 93 |
| Example 2 | R.T. | 86 | 280 | 0.69 | 3 | 84 | 96 | 94 |
| Example 3 | 215 | 111 | 300 | 0.31 | 1.07 | 84 | 93 | 90 |
| Example 4 | 170 | 86 | 230 | 0.35 | 1.26 | 84 | 94 | 90 |
| Example 5 | 215 | 86 | 210 | 0.31 | 0.39 | 87 | 81 | 71 |
| Example 6 | 215 | 86 | 180 | 0.31 | 0.37 | 87 | 75 | 64 |
| Example 7 | 215 | 190 | 280 | 0.31 | 0.77 | 96 | 86 | 76 |
| Comparative | 215 | 40 | 300 | 0.28 | 0.21 | 88 | 65 | 54 |
| example 1 | | | | | | | | |

While there has been described and illustrated a transparent conductive film comprising indium-zinc oxide as its main component and having high transmission from the visible to the infrared wavelength region, it will be apparent to those skilled in the art that modifications and variations are possible without deviating from the broad scope of the invention which shall be limited solely by the scope of the claims appended hereto.

Having thus described our invention, what we claim as new and desire to secure by Letters Patent is:

1. A method for fabricating a structure comprising the steps of:
preparing a transparent conductive film formed on a substrate, said transparent conductive film comprising indium-zinc oxide; and
heating said transparent conductive film in an ambient atmosphere having less than 21% oxygen.

2. The method as set forth in claim 1 wherein said transparent conductive film is heated at a temperature in the range between about 150 and about 350° C.

3. The method as set forth in claim 1 wherein said transparent conductive film is heated at a temperature in the range between about 230 and about 300° C.

4. The method as set forth in claim 2 wherein said transparent conductive film is heated for a time in the range from about 10 to about 120 minutes.

5. The method as set forth in claim 1 wherein said transparent conductive film is formed on said substrate by sputtering, the temperature of said substrate being in the range from about 22 to about 250C.

6. The method as set forth in claim 1 wherein said ambient atmosphere of low-concentration oxygen is selected from a group consisting of nitrogen, the air, and a mixture thereof.

7. The method as set forth in claim 1 wherein said ambient atmosphere of low-concentration oxygen does not contain oxygen higher in concentration than the concentration of oxygen in the air.

8. The method as set forth in claim 1 wherein said transparent conductive film is substantially in amorphous form or microcrystalline form.

9. A method for fabricating a transparent conductive film which exhibits a transmittance of about 80% or more in a wavelength region from about 450 to about 3200 nm, the method comprising the steps of:
forming a transparent conductive film up to a thickness of about 100 nm onto a substrate, said transparent conductive film comprising indium-zinc oxide; and
heating said transparent conductive film at a temperature in the range from about 230 to about 300° C. in an ambient atmosphere having less than 21% oxygen.

10. A structure having a transparent conductive film which comprises an indium-zinc oxide on a substrate, wherein said transparent conductive film has a transmittance of about 70% or more in an infrared wavelength region from about 800 to about 3200 nm.

11. The structure as set forth in claim 10 wherein said transparent conductive film has a transmittance of about 80% or more in said infrared wavelength region.

12. The structure as set forth in claim 10 wherein said transparent conductive film has a transmittance of about 80% or more in a visible-light wavelength region from about 450 to about 800 nm.

13. The structure as set forth in claim 10 wherein said transparent conductive film comprises zinc in the range from about 5 to about 20 atomic % and indium in the range from about 5 to about 40 atomic %.

14. The structure as set forth in claim 10 wherein said transparent conductive film is substantially in amorphous form or microcrystalline form.

15. The structure as set forth in claim 10 wherein said transparent conductive film has an electrical resistivity of about 3.0×10⁻³ Ω-cm or less.

16. The structure as set forth in claim 10 wherein said transparent conductive film has a thickness of about 200 nm or less.

17. The structure as set forth in claim 11 wherein said transparent conductive film has a thickness of about 100 nm or less.

18. A transparent conductive film having at least an 80% transmission in the infrared wavelength region, fabricated by heating the transparent conductive film comprising an indium-zinc oxide in an ambient atmosphere of up to 21% oxygen.
